(19) United States
(12) Patent Application Publication
(10) Pub. No.: US 2022/0415672 A1
(43) Pub. Date: Dec. 29, 2022

(54) APPARATUS FOR TREATING SUBSTRATE AND METHOD FOR TREATING SUBSTRATE

(71) Applicant: SEMES CO., LTD., Cheonan-si (KR)

(72) Inventors: KWANG RYUL KIM, Suwon-si (KR); JUNG HOON PARK, Sejong-si (KR); YUN SANG KIM, Seongnam-si (KR)

(21) Appl. No.: 17/846,166

(22) Filed: Jun. 22, 2022

(30) Foreign Application Priority Data
Jun. 23, 2021 (KR) 10-2021-0081498

(51) Int. Cl. H01L 21/67; H01L 21/3065

(52) U.S. Cl. CPC H01L 21/67063; H01L 21/3065

(57) ABSTRACT

The inventive concept provides a substrate treating apparatus. The substrate treating apparatus includes a chamber providing a treating space; a substrate support unit provided in the treating space; a window provided at a top of the chamber; and an optical module provided over the window and configured to transmit a laser beam to a substrate through the window, and wherein the optical module includes: a homogenizing optics configured to homogenize the laser beam to a uniform beam profile; and an imaging optics configured to control the size of the laser beam.

### CROSS-REFERENCE TO RELATED APPLICATIONS

A claim for priority under 35 U.S.C. § 119 is made to Korean Patent Application No. 10-2021-0081498 filed on Jun. 23, 2021, in the Korean Intellectual Property Office, the entire contents of which are hereby incorporated by reference.

### BACKGROUND

Embodiments of the inventive concept described herein relate to a substrate treating apparatus and a substrate treating method.

A plasma may be used in a treating process of a substrate. For example, the plasma may be used in an etching process, a deposition process, or a dry cleaning process. The plasma is generated by a very high temperature, a strong electric field, or a high frequency electric field (RF electromagnetic field), and the plasma refers to an ionized gas state consisting of ions, electrons, radicals, or the like. The dry cleaning process, an ashing process, or the etching process using the plasma is performed by reacting or colliding ions or radical particles contained in the plasma with the substrate.

In addition, in order to manufacture a semiconductor device, various heat treatments such as a reforming treatment and an annealing treatment are repeated on a semiconductor wafer. In addition, highly densifying, multilayering, and higher integrating the semiconductor device is becoming more difficult to specify each year, and thus a uniformity improvement and a film quality improvement are required within various heat-treated semiconductor wafer surfaces.

In a manufacturing process of the semiconductor device, a step of moving between an apparatus using the plasma and an annealing apparatus is involved, and a UPH is affected according to a moving time between the apparatuses.

In addition, recently, an ALE is applied as the etching process. The ALE (atomic layer etching) is a method of removing a controlled amount of material, using an adsorption reaction that modifies a film of the surface and a desorption reaction that removes a modified film. The adsorption reaction has a high reactivity at a low temperature (e.g., room temperature), and the desorption reaction has high reactivity at a very high temperature (e.g., 500° C. or more).

However, when the substrate is heated to a high temperature in a process, it takes a long time to heat the substrate and also a long time to cool a heated substrate, and costs for cooling are also required. Therefore the UPH is lowered, and thus a temperature is fixed near a temperature required for the desorption reaction. However, as the adsorption reaction must also be considered, it is fixed within a range that does not reach a temperature range at which the desorption reaction is maximized.

In an environment where the temperature cannot be changed freely, a process window is also limited.

On the other hand, when heating the substrate using a heater provided at an electrostatic chuck of the conventional art, a damage may occur such as a breaking of the wafer at high temperature conditions of 500° C. or higher.

### SUMMARY

Embodiments of the inventive concept provide a substrate treating apparatus and a substrate treating method capable of solving the above problems.

Embodiments of the inventive concept provide a substrate treating apparatus and a substrate treating method capable of efficiently treating a substrate.

Embodiments of the inventive concept provide a substrate treating apparatus capable of increasing a production amount per hour (UPH, units per hour) in a manufacturing of a semiconductor device on a substrate.

Embodiments of the inventive concept provide a substrate treating apparatus capable of decreasing a footprint of a facility.

Embodiments of the inventive concept provide a substrate treating apparatus and a substrate treating method capable of decreasing a process time while fulfilling both a temperature for an absorption reaction and a temperature for a desorption reaction.

Embodiments of the inventive concept provide a substrate treating apparatus and a substrate treating method capable of increasing a process window.

Embodiments of the inventive concept provide a substrate treating apparatus and a substrate treating method capable of being heated to a high temperature while being free from a damage to a wafer.

The technical objectives of the inventive concept are not limited to the above-mentioned ones, and the other unmentioned technical objects will become apparent to those skilled in the art from the following description.

The inventive concept provides a substrate treating apparatus. The substrate treating apparatus includes: a chamber providing a treating space; a substrate support unit provided in the treating space; a window provided at a top of the chamber; and an optical module provided over the window and configured to transmit a laser beam to a substrate through the window, and wherein the optical module comprises: a homogenizing optics configured to homogenize the laser beam to a uniform beam profile; and an imaging optics configured to control the size of the laser beam.

In an embodiment, the substrate treating apparatus further includes: a transparent electrode provided at an optical path of the laser beam; and a bottom electrode positioned below the substrate.

In an embodiment, the transparent electrode is on the window.

In an embodiment, the substrate treating apparatus further includes a high frequency power source connected to the transparent electrode or the bottom electrode or both the transparent electrode and the bottom electrode.

In an embodiment, the transparent electrode comprises at least one selected from the group consisting of an ITO (indium tin oxide), an AZO, an FTO, an ATO, an SnO2, a ZnO, an IrO2, an RuO2, a graphene, a metal nanowire, a CNT, and any combinations thereof and any mixtures thereof.

In an embodiment, the transparent electrode is provided to coat the window.

In an embodiment, the window comprises or made of a quartz material.

In an embodiment, the optical module further comprises a collimation optics.

In an embodiment, the window is positioned at an optical path of a laser beam from the optical module.

In an embodiment, the substrate treating apparatus further includes: a laser beam generator configured to generate the laser beam; and an optical fiber optically connecting the laser beam generator and the optical module, and wherein a laser beam transmitted to the optical module is a pulse laser beam.

In an embodiment, a pulse width of the pulse laser beam is a picosecond to a nanosecond.

In an embodiment, a pulse duration of the pulse laser beam is 1 nanosecond to 100 miliseconds.

In an embodiment, the laser beam is configured to heat the substrate to a temperature of 500° C. or above.

In an embodiment, the laser beam is configured to apply an energy of 10 mJ/cm² or above to the substrate.

In an embodiment, the substrate treating apparatus further includes: a transparent electrode provided at an optical path of the laser beam; a bottom electrode positioned below the substrate; a high frequency power source connected to the transparent electrode or the bottom electrode or both the transparent electrode and the bottom electrode; a laser beam generator configured to generate the laser beam; an optical fiber connected between and to the laser beam generator and the optical module; a gas supply unit configured to introduce a gas to the treating space; an exhaust unit configured to exhaust an atmosphere within the treating space to an outside of the treating space; and a controller, and wherein the controller is configured to performs: first operation of control the gas supply unit to introduce a first process gas to the treating space, and control the high frequency power source to excite the introduced first process gas to a plasma to treat the substrate; second operation of control the gas supply unit to introduce a purge gas to the treating space, and control the exhaust unit to exhaust the treating space; third operation of control the gas supply unit to introduce a second process gas to the treating space, control the high frequency power source to excite the introduced second process gas to the plasma, and control the laser beam generator to apply the laser beam as a pulse to treat the substrate; and fourth operation of control the gas control unit to introduce the purge gas to the treating space, and control the exhaust unit to exhaust the treating space, and wherein the first to the fourth operations are performed sequentially with at least two cycles.

The inventive concept provides a substrate treating method. The substrate treating method includes heating a substrate by transmitting a pulse laser beam to a surface of the substrate, and wherein the pulse laser beam is transmitted to the surface of the substrate through: a homogenizing optics configured to homogenize a laser beam to a uniform beam profile; and an imaging optics configured to control the size of the laser beam.

In an embodiment, a pulse width of the pulse laser beam is a picosecond to a nanosecond.

In an embodiment, the substrate is provided within a chamber providing a treating space, and supported by a substrate support unit including a bottom electrode, and the laser beam, after passing the imaging optics, further passes through a top electrode provided at a top of the chamber, to the substrate and wherein the top electrode comprises: a window including or being made of a quartz; and a transparent electrode stacked on the window, and wherein a high frequency power source is applied to the transparent electrode or the bottom electrode or both the transparent electrode and the bottom electrode.

In an embodiment, the substrate treating method further includes: a first operation of treating the substrate by introducing a first process gas to the treating space, and exciting the introduced first process gas to a plasma; a second operation of introducing a purge gas to the treating space, and exhausting the treating space; a third operation of introducing a second process gas to the treating space, exciting the introduced second process gas to a plasma, and applying the pulse laser beam; and a fourth operation of applying the purge gas to the treating space, and exhausting the treating space, and wherein the first to the fourth operations are sequentially performed with at least two cycles.

The inventive concept provides a substrate treating apparatus. The substrate treating apparatus includes: a chamber providing a treating space; a substrate support unit provided in the treating space; a window provided at a top of the chamber; and a transparent electrode provided to coat the window; a laser beam generator configured to generate a laser beam; an optical module provided over the window and configured to transmit the laser beam to a substrate; and an optical fiber connecting the laser beam generator and the optical module, and wherein the optical module comprises: a collimation optics; a homogenizing optics configured to homogenize the laser beam to a uniform beam profile; and an imaging optics configured to control a size of the laser beam, and wherein the laser beam transmitted to the optic module is a pulse laser beam.

According to an embodiment of the inventive concept, a substrate may be efficiently treated.

According to an embodiment of the inventive concept, a production amount per hour (UPH, units per hour) in a manufacturing of a semiconductor device on a substrate may be increased.

According to an embodiment of the inventive concept, a footprint of a facility may be decreased.

According to an embodiment of the inventive concept, a temperature required for a desorption reaction may be reached and the desorption reaction may be obtained within milliseconds (ms).

According to an embodiment of the inventive concept, although a substrate is heated to a high temperature for an adsorption reaction, a surface of the substrate is exposed to the high temperature for only a very short time, thereby preventing the substrate from being cracked due to exposure to the high temperature.

According to an embodiment of the inventive concept, an absorption process can be performed at 500° C. or higher.

According to an embodiment of the inventive concept, a process window may be increased, such as an increase in a selection range of a precursor.

The effects of the inventive concept are not limited to the above-mentioned ones, and the other unmentioned effects will become apparent to those skilled in the art from the following description.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 illustrates a substrate treating apparatus according to an embodiment of the inventive concept.

FIG. 2 illustrates performing an ALE process as a use example of the substrate treating apparatus, and illustrates a state of the apparatus when performing an adsorption process.

FIG. 3 illustrates performing the ALE process as a use example of the substrate treating apparatus, and illustrates a state of the apparatus when performing a purge process.

FIG. 4 illustrates performing the ALE process as a use example of the substrate treating apparatus, and illustrates a state of the apparatus when performing a desorption process.

FIG. 5 illustrates performing the ALE process as a use example of the substrate treating apparatus, and illustrates a state of the apparatus when performing a purge process.

### DETAILED DESCRIPTION

Some detailed example embodiments are disclosed herein. However, specific structural and functional details disclosed herein are merely representative for purposes of describing example embodiments. Example embodiments may, however, be embodied in many alternate forms and should not be construed as limited to only the example embodiments set forth herein.

Accordingly, while example embodiments are capable of various modifications and alternative forms, example embodiments thereof are shown by way of example in the drawings and will herein be described in detail. It should be understood, however, that there is no intent to limit example embodiments to the particular forms disclosed, but to the contrary, example embodiments are to cover all modifications, equivalents, and alternatives thereof. Like numbers refer to like elements throughout the description of the figures.

It should be understood that when an element or layer is referred to as being “on,” “connected to,” “coupled to,” “attached to,” “adjacent to,” “covering,” etc. another element or layer, it may be directly on, connected to, coupled to, attached to, adjacent to, covering, etc. the other element or layer or intervening elements or layers may be present. In contrast, when an element is referred to as being “directly on,” “directly connected to,” “directly coupled to,” etc. another element or layer, there are no intervening elements or layers present. Like numbers refer to like elements throughout the specification. As used herein, the term “and/or” includes any and all combinations or sub-combinations of one or more of the associated listed items.

It should be understood that, although the terms first, second, third, etc. may be used herein to describe various elements, regions, layers and/or sections, these elements, regions, layers, and/or sections should not be limited by these terms. These terms are only used to distinguish one element, region, layer, or section from another region, layer, or section. Thus, a first element, region, layer, or section discussed below could be termed a second element, region, layer, or section without departing from the teachings of example embodiments.

Spatially relative terms (e.g., “beneath,” “below,” “lower,” “above,” “upper,” and the like) may be used herein for ease of description to describe one element or feature's relationship to another element(s) or feature(s) as illustrated in the figures. It should be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” may encompass both an orientation of above and below. The device may be otherwise oriented (rotated 90 degrees or at other orientations) and the spatially relative descriptors used herein interpreted accordingly.

The terminology used herein is for the purpose of describing various example embodiments only and is not intended to be limiting of example embodiments. As used herein, the singular forms “a,” “an,” and “the” are intended to include the plural forms as well, unless the context clearly indicates otherwise. It will be further understood that the terms “includes,” “including,” “comprises,” and/or “comprising,” when used in this specification, specify the presence of stated features, integers, steps, operations, and/or elements, but do not preclude the presence or addition of one or more other features, integers, steps, operations, elements, and/or groups thereof.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

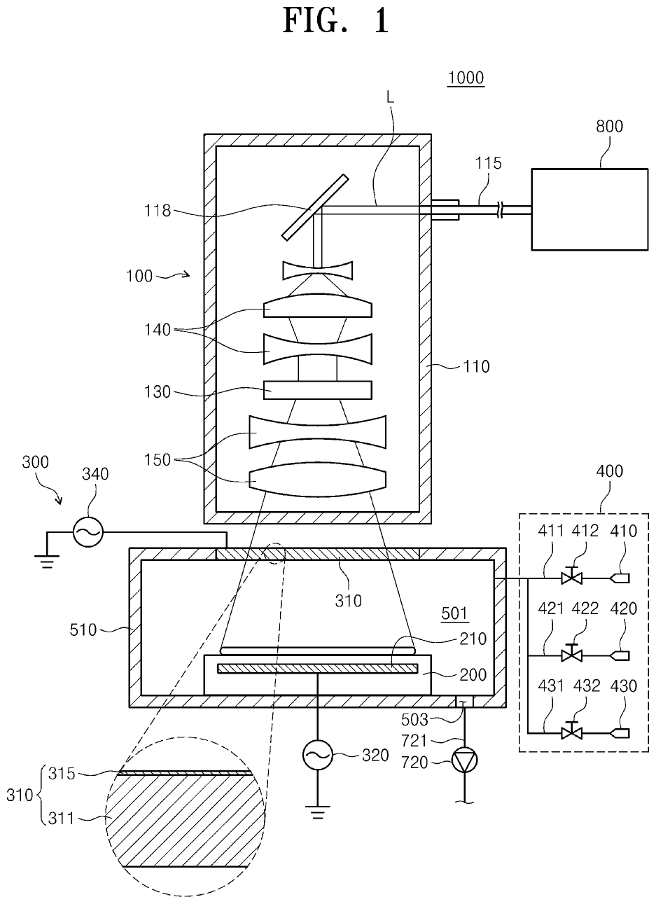

FIG. 1 illustrates a substrate treating apparatus according to an embodiment of the inventive concept.

The substrate treating apparatus 1000 may include a process chamber 510, a support unit 200, a gas supply unit 400, a plasma source 300, and an optical module 100. The substrate treating apparatus 1000 may treat a substrate W using a plasma.

The process chamber 510 has an inner space 501 for performing a process therein. An exhaust hole 503 is formed on a bottom of the process chamber 510. The exhaust hole 503 is connected to an exhaust line on which a pump 720 is mounted. The reaction by-products generated in the process and a gas remaining in the inner space 501 are exhausted through the exhaust hole 503 by an exhaust pressure applied by the pump 720. In addition, the inner space 501 of the process chamber 510 is depressurized to a desired pressure by an exhaust process. The pump 720 may be a vacuum pump.

An opening (not shown) is formed on a sidewall of the process chamber 510. The opening (not shown) functions as a passage through which the substrate W enters and exits the process chamber 510. The opening (not shown) is opened and closed by a door assembly (not shown).

The support unit 200 is located in a lower region of the inner space 501. The support unit 200 may include an electrostatic chuck ESC. The electrostatic chuck ESC clamps the substrate W with an electrostatic force. Unlike this, the support unit 200 may support the substrate W in various ways such as a mechanical clamping. The support unit 200 may include a bottom electrode 210 made of a metal material. The bottom electrode 210 may be made of an aluminum material. The bottom electrode 210 may have a plate shape. In addition, a flow path may be formed inside the support unit 200. The flow path is provided as a passage through which a cooling fluid circulates. The cooling fluid absorbs a heat from the substrate W through the support unit W and cools it. The support unit 200 and the substrate W may be cooled by a circulation of the cooling fluid, and the substrate W may be maintained at a desired temperature.

The gas supply unit 400 supplies a gas required for a process to the inner space 501. The gas supply unit 400 includes a first gas supply line 411 connected to a first gas supply source 410, a second gas supply line 421 connected to a second gas supply source 420, and a third gas supply line 431 connected to a third gas supply source 430. A first gas and a second gas may be reaction gases for treating the substrate, and a third gas may be a purge gas for purging. A first valve 412 may be installed at the first gas supply line 411 to open and close a passage or to adjust a flow rate of a fluid flowing through the passage. A second valve 422 may be installed at the second gas supply line 421 to open and close a passage or to adjust a flow rate of a fluid flowing through the passage. A third valve 432 may be installed at the third gas supply line 431 to open and close a passage or to adjust a flow rate of the fluid flowing through the passage.

The plasma source 300 generates the plasma from a process gas remaining at a discharge space. The discharge space may correspond to an upper region of the inner space 501 above the support unit 200. The plasma source 300 may have a capacitive coupled plasma source. The plasma source 300 may include a top electrode 315, a bottom electrode 210 of the support unit 200, a first high frequency power source 320, and a second high frequency power source 330. The top electrode 315 and the bottom electrode 210 may be provided to face each other in a top/down direction.

The top electrode 315 is provided on the window 311. The top electrode 315 may be provided to coat the window 311. The top electrode 315 is configured to transmit a laser beam applied from the optical module 100 to the substrate W without a loss (or in a state where the loss is minimized). The top electrode 315 is provided as a transparent electrode. The top electrode 315 may be an indium tin oxide (ITO). In addition, the top electrode 315 may be formed of one selected from the group consisting of an AZO, an FTO, an ATO, a SnO2, a ZnO, a IrO2, a RuO2, a graphene, a metal nanowire, a CNT, any combinations thereof and any mixtures thereof. The top electrode 315 is provided to have a first thickness or less. The first thickness may be selected such that through which a light or a microwave may be transmittable with respect to a determined material. The first thickness varies depending on a material determined as the top electrode 315. As used herein the term “transmittable” may mean that a transmittance of the light or microwave or laser beam or the like is not significantly affected or blocked. In an embodiment, when the top electrode 315 is made of or comprises the ITO, the first thickness may be 1 μm. The top electrode 315 and the bottom electrode 210 cooperate with each other to generate an electric field when an RF voltage is applied to any one or both thereof. According to an embodiment, the top electrode 315 may be grounded, and the high frequency power may be applied to the bottom electrode 210 by the first high frequency power source 320. Selectively, a power by the second high frequency power source 330 may be applied to the top electrode 315, and the bottom electrode 210 may be grounded. In addition, the high frequency power may be selectively applied to both the top electrode 315 and the bottom electrode 210.

The window 311 may have a disk shape. The window 311 may comprise or be made of a transmittable material capable of transmitting a laser beam therethrough to the substrate W to heat the substrate W. The window 311 may comprise a material having a corrosion resistance. As an embodiment of the window 311, a quartz may be provided.

The laser beam transmitted via the optical module 100 and through the window 311 heats the substrate W on the support unit 200. The laser beam is transmitted in the form of a pulse to the substrate W. According to an embodiment of the inventive concept, since the surface of the substrate is selectively heated by a pulse-type laser beam, the substrate is heated at a high speed and is cooled at high speed and thus the surface of the substrate may be heated to a target temperature within a short time, thereby reducing a process time.

The optical module 100 will be described in more detail. The optical module 100 includes a collimation optics 140, a homogenizing optics 130, and an imaging optics 150. The collimation optics 140, the homogenizing optics 130, and the imaging optics 150 may be accommodated and protected at the housing 110.

The collimation optics 140 converts the laser beam into a parallel light. The homogenizing optics 130 homogenizes the laser beam with a uniform beam profile. The imaging optics 150 controls a size of the laser beam. For example, the imaging optics 150 controls the size of the laser beam to the size of the substrate. The laser beam is transmitted to the substrate W through the collimation optics 140, the homogenizing optics 130, and the imaging optics 150, and through the window 311. The collimation optics 140, the homogenizing optics 130, and the imaging optics 150 may be sequentially arranged along a traveling direction of a light. However, an order in which the collimation optics 140, the homogenizing optics 130, and the imaging optics 150 are provided is not limited to the illustration and may be appropriately selected as needed. Since the laser beam irradiated to the substrate W is a large-area laser beam suitable for the size of the substrate W, the entire substrate W may be heated at once.

A DOE (diffractive optical element) or a micro (multi) lens array may be used as the optical module 100.

The laser beam is generated from the laser beam generator 800. The laser beam generator 800 and the optical module 100 are optically connected via an optical fiber 115. The optical fiber 115 transfers the laser beam generated from the laser beam generator 800 to the optical module 100 without a loss. The laser beam may have a wavelength that is not absorbed by the top electrode 315. In an embodiment, the laser beam may have a wavelength in a range of 500 nm to 550 nm.

The laser beam transmitted to the optical module 100 is a pulse laser beam having a pulse form. A pulse width of the pulse laser beam is a picosecond to a nanosecond. A pulse duration of the pulse laser beam is 1 nanosecond to 100 milliseconds. The pulse laser beam may heat the substrate W to 500° C. or above. It may take 1 second or less to heat the substrate W to 500° C. or above. The pulse laser beam applies an energy of 10 mJ/cm² or more to the substrate W. When the laser beam is applied to the substrate W in a pulse form, the surface of the substrate W is quickly heated but not deeply heated, and also, after stopping the irradiation of the laser beam, the substrate W may be quickly cooled and thus prevented from being damaged by a high heat.

According to an embodiment, the laser beam generator 800 may be connected through a side surface of the optical module 100. That is, a port to which the optical fiber 115 is coupled is provided on a top side of the housing 110. In another aspect, when the collimation optics 140, the homogenizing optics 130, and the imaging optics 150 are aligned in a first direction, the laser beam may be incident in a second direction perpendicular to the first direction. A mirror 118 switches an optical path of the laser beam incident in the second direction to the first direction. When the port to which the optical fiber 115 is coupled is provided on the top side of the housing 110, a height of the substrate treating apparatus 1000 may be reduced.

Each component of the substrate treating apparatus 1000 may be controlled by a controller (not shown). The controller (not shown) may control the entire operation of the substrate treating apparatus 1000. The controller (not shown) may include a central processing unit (CPU), a read only memory (ROM), and a random access memory (RAM). The CPU executes a desired processing such as an etching treatment according to various recipes stored in a storage area thereof.

In the recipe, a control information of the apparatus for a process condition is input. Meanwhile, a recipe indicating these programs and treating conditions may be stored in a non-transitory computer-readable medium. The non-transitory computer-readable medium refer to a medium that stores a data semi-permanently and can be read by a computer, rather than a medium that stores the data for a short period of time, such as a register, a cache, or a memory. Specifically, various applications or programs described above may be stored and provided in a non-transitory readable medium such as a CD, a DVD, a hard disk, a Blu-ray disk, a USB, a memory card, a ROM, or the like.

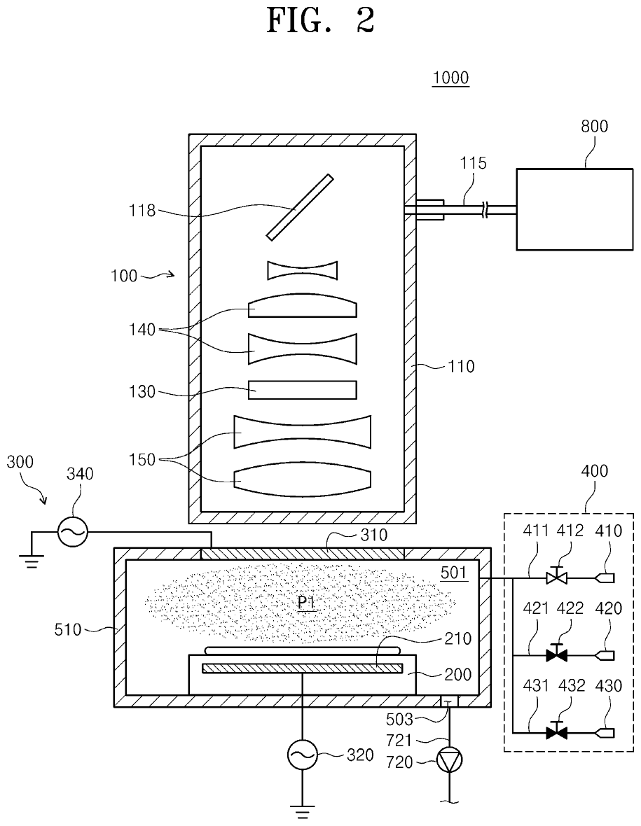

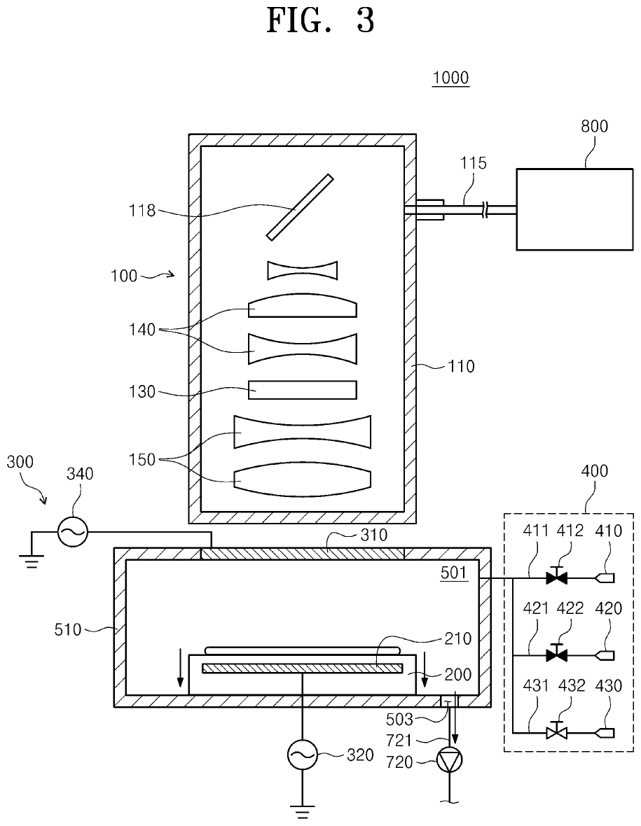

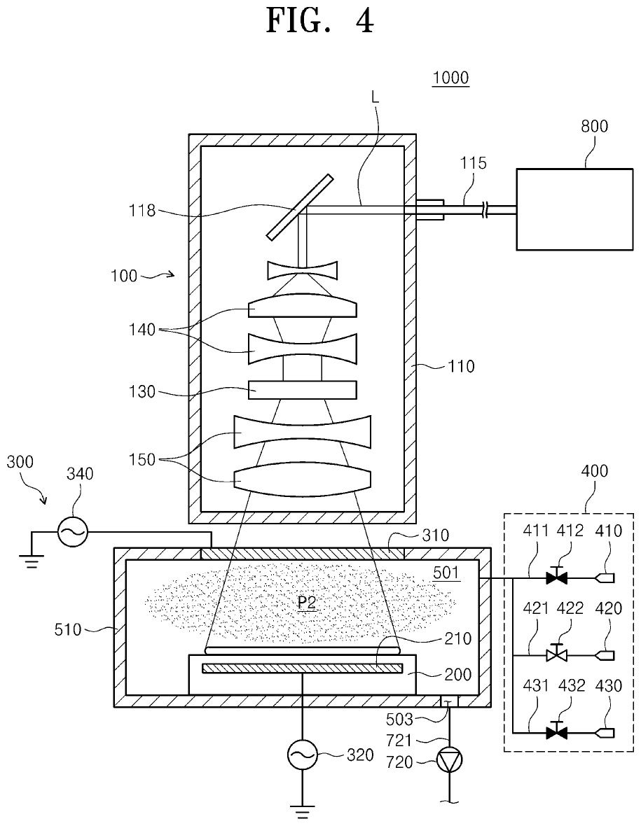

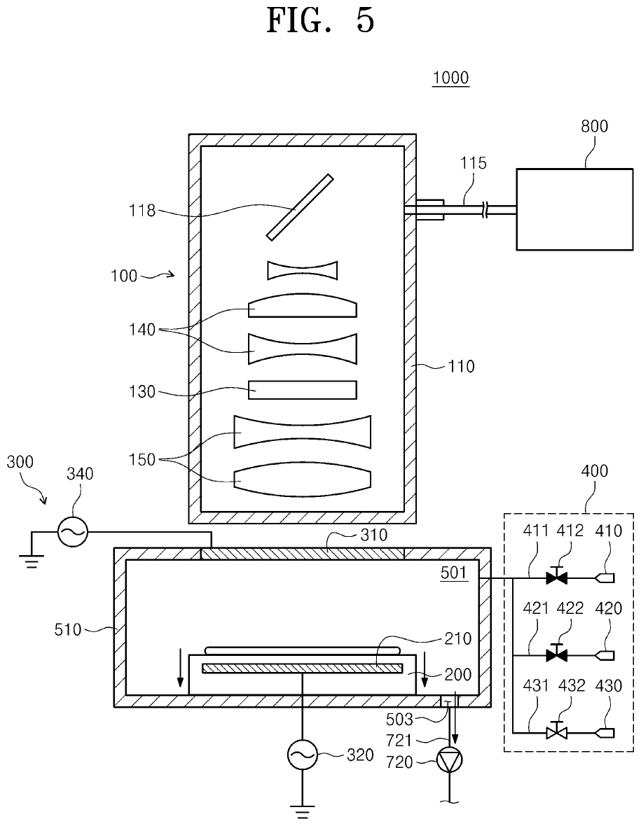

FIG. 2 to FIG. 5 schematically a substrate treating apparatus performing ALE (atomic layer etching) processes wherein FIG. 2 illustrates the substrate treating apparatus performing an adsorption process, FIG. 3 illustrates the substrate treating apparatus performing a purge process, FIG. 4 illustrates the substrate treating apparatus a desorption process, and FIG. 5 illustrates the substrate treating apparatus performing a purge process. The ALE processes using the substrate treating apparatus in accordance with an embodiment of the inventive concept will be described with reference to FIG. 2 to FIG. 5 sequentially.

Referring to FIG. 2, for the adsorption process, the first gas is excited into a plasma while supplying the first gas to a reaction space. A plasma excited from the first gas is adsorbed on a surface of the substrate W to modify the surface of the substrate W. The adsorption process is performed in a state where the substrate W is at a first temperature. The first temperature is a temperature at which the plasma excited from the first gas is adsorbed on the surface of the substrate W. In an embodiment, the first temperature may be around 20° C. As the substrate W is treated at a temperature at which an adsorption of the surface of the substrate W is maximized, a time required for an adsorption reaction may be reduced. In an embodiment, the adsorption reaction may be performed within 1 second.

Referring to FIG. 3, after the adsorption process is completed, a third gas is supplied to the reaction space W. The third gas may be a nitrogen. In addition, an atmosphere of the inner space 501 is exhausted. The inner space 501 is purged and a remaining process gas and process by-products are exhausted through the exhaust hole 503. The purge process may be performed in about 5 seconds, but is not limited thereto, and it is sufficient to perform until the remaining process gas and process by-products are properly exhausted.

Referring to FIG. 4, for the desorption process, the second gas is excited with the plasma while supplying the second gas to the reaction space. The plasma excited from the second gas removes modified surface of the substrate W. The surface of the substrate W is heated by a laser beam emitted from the optical module 100. The laser beam applies an energy of 10 mJ/cm² to 100 mJ/cm² to the substrate W. A heat on a bottom side of the substrate W may be cooled by a cooling fluid flowing through a flow path of the support unit 200. The laser beam is applied with a pulse energy. In the desorption process, the surface of the substrate W is made to reach a second temperature. The second temperature is a temperature at which a desorption performed by a plasma excited from the second gas is maximized. In an embodiment, the second temperature may be 500° C. or more. As the substrate W is treated at a temperature at which the adsorption of the surface of the substrate W is maximized, a time required for an adsorption reaction may be reduced. In an embodiment, a desorption reaction may be performed within 1 ms. The surface of the substrate W may be heated to 500° C. or more by the laser pulse beam and may be instantaneously cooled by stopping the laser pulse beam.

Referring to FIG. 5, after the desorption process is completed, the third gas is supplied to the reaction space W. The third gas may be a nitrogen. In addition, the atmosphere of the inner space 501 is exhausted. The inner space 501 is purged and a remaining process gas and process by-products are exhausted through the exhaust hole 503. The purge process may be performed in about 5 seconds, but is not limited thereto, and it is sufficient to perform until the remaining process gas and process by-products are properly exhausted.

The above-mentioned adsorption-purge-desorption-purge process is repeated a plurality of times until a desired etching condition is achieved.

Although performing the ALE process has been described above as an example, the substrate treating apparatus of this inventive concept may be applied to an annealing treatment of the substrate W. It can also be applied to other high-temperature heating processes not described.

The effects of the inventive concept are not limited to the above-mentioned effects, and the unmentioned effects can be clearly understood by those skilled in the art to which the inventive concept pertains from the specification and the accompanying drawings.

Although the preferred embodiment of the inventive concept has been illustrated and described until now, the inventive concept is not limited to the above-described specific embodiment, and it is noted that an ordinary person in the art, to which the inventive concept pertains, may be variously carry out the inventive concept without departing from the essence of the inventive concept claimed in the claims and the modifications should not be construed separately from the technical spirit or prospect of the inventive concept.

What is claimed is:

1. A substrate treating apparatus comprising:
a chamber providing a treating space;
a substrate support unit provided in the treating space;
a window provided at a top of the chamber; and
an optical module provided over the window and configured to transmit a laser beam to a substrate through the window, and
wherein the optical module comprises:
a homogenizing optics configured to homogenize the laser beam to a uniform beam profile; and
an imaging optics configured to control the size of the laser beam.

2. The substrate treating apparatus of claim 1 further comprising:
a transparent electrode provided at an optical path of the laser beam; and
a bottom electrode positioned below the substrate.

3. The substrate treating apparatus of claim 2, wherein the transparent electrode is on the window.

4. The substrate treating apparatus of claim 2 further comprising a high frequency power source connected to the transparent electrode or the bottom electrode or both the transparent electrode and the bottom electrode.

5. The substrate treating apparatus of claim 2, wherein the transparent electrode comprises at least one selected from the group consisting of an ITO (indium tin oxide), an AZO, an FTO, an ATO, an SnO2, a ZnO, an IrO2, an RuO2, a graphene, a metal nanowire, a CNT, and any combinations thereof and any mixtures thereof.

6. The substrate treating apparatus of claim 2, wherein the transparent electrode is provided to coat the window.

7. The substrate treating apparatus of claim 1, wherein the window comprises or made of a quartz material.

8. The substrate treating apparatus of claim 1, wherein the optical module further comprises a collimation optics.

9. The substrate treating apparatus of claim 1, wherein the window is positioned at an optical path of a laser beam from the optical module.

10. The substrate treating apparatus of claim 1 further comprising:
a laser beam generator configured to generate the laser beam; and
an optical fiber optically connecting the laser beam generator and the optical module, and
wherein a laser beam transmitted to the optical module is a pulse laser beam.

11. The substrate treating apparatus of claim 10, wherein a pulse width of the pulse laser beam is a picosecond to a nanosecond.

12. The substrate treating apparatus of claim 10, wherein a pulse duration of the pulse laser beam is 1 nanosecond to 100 miliseconds.

13. The substrate treating apparatus of claim 1, wherein the laser beam is configured to heat the substrate to a temperature of 500° C. or above.

14. The substrate treating apparatus of claim 1, wherein the laser beam is configured to apply an energy of 10 mJ/cm² or above to the substrate.

15. The substrate treating apparatus of claim 1 further comprising:
a transparent electrode provided at an optical path of the laser beam;
a bottom electrode positioned below the substrate;
a high frequency power source connected to the transparent electrode or the bottom electrode or both the transparent electrode and the bottom electrode;
a laser beam generator configured to generate the laser beam;
an optical fiber connected between and to the laser beam generator and the optical module;
a gas supply unit configured to introduce a gas to the treating space;
an exhaust unit configured to exhaust an atmosphere within the treating space to an outside of the treating space; and
a controller, and
wherein the controller is configured to performs:
first operation of control the gas supply unit to introduce a first process gas to the treating space, and control the high frequency power source to excite the introduced first process gas to a plasma to treat the substrate;
second operation of control the gas supply unit to introduce a purge gas to the treating space, and control the exhaust unit to exhaust the treating space;
third operation of control the gas supply unit to introduce a second process gas to the treating space, control the high frequency power source to excite the introduced second process gas to the plasma, and control the laser beam generator to apply the laser beam as a pulse to treat the substrate; and
fourth operation of control the gas control unit to introduce the purge gas to the treating space, and control the exhaust unit to exhaust the treating space, and
wherein the first to the fourth operations are performed sequentially with at least two cycles.

16. A substrate treating apparatus comprising:
a chamber providing a treating space;
a substrate support unit provided in the treating space;
a window provided at a top of the chamber; and
a transparent electrode provided to coat the window;
a laser beam generator configured to generate a laser beam;
an optical module provided over the window and configured to transmit the laser beam to a substrate; and
an optical fiber connecting the laser beam generator and the optical module, and
wherein the optical module comprises:
a collimation optics;
a homogenizing optics configured to homogenize the laser beam to a uniform beam profile; and
an imaging optics configured to control a size of the laser beam, and
wherein the laser beam transmitted to the optic module is a pulse laser beam.
